(19) United States
(12) Patent Application Publication
(10) Pub. No.: US 2017/0294465 A1
(43) Pub. Date: Oct. 12, 2017

(54) Film Patterning Method

(71) Applicants: BOE Technology Group Co., Ltd., Beijing (CN); Beijing BOE Optoelectronics Technology Co., Ltd., Beijing (CN)

(72) Inventors: Xiaoguang Pei, Beijing (CN); Haisheng Zhao, Beijing (CN); Zhilong Peng, Beijing (CN); Hongxi Xiao, Beijing (CN); Chong Liu, Beijing (CN); Zhilian Xiao, Beijing (CN); Zijin Lin, Beijing (CN); Yunfei Bai, Beijing (CN); Huigang Jiang, Beijing (CN); Yiping Dong, Beijing (CN); Hao Chen, Beijing (CN); Miao Qiu, Beijing (CN); Kuo Chang, Beijing (CN)

(73) Assignees: BOE Technology Group Co., Ltd., Beijing (CN); Beijing BOE Optoelectronics Technology Co., Ltd., Beijing (CN)

(21) Appl. No.: 15/511,519

(22) PCT Filed: Jul. 28, 2016
(86) PCT No.: PCT/CN2016/092088

§ 371 Date: Mar. 15, 2017

(30) Foreign Application Priority Data
Oct. 30, 2015 (CN) 201510729734.8

(51) Int. Cl. H01L 27/12; H01L 21/027; H01L 29/786; H01L 21/02

(52) U.S. Cl. CPC H01L 27/1288; H01L 27/127; H01L 21/02057; H01L 21/0274; H01L 27/1222; H01L 29/78669; G06F 2203/04103; G06F 3/041

(57) ABSTRACT

A film patterning method is provided. The method comprises: performing a dry etching process on a film to be patterned, so as to form a patterned film; removing a suspended particle on the patterned film; and performing another dry etching process on the patterned film after the suspended particle is removed, to form a final pattern of the film. By moving or completely removing the suspended particle on the patterned film and then performing another dry etching process on the patterned film to etch away the etching residue, existence of the etching residue is completely avoided in the final pattern of the film, so that the product yield is improved and the product quality is ensured.

### TECHNICAL FIELD

The present disclosure relates to a film patterning method.

### BACKGROUND

At present, many important components within a display panel include a variety of films having a pattern. In a film patterning process, a suspended particle in an environment or an apparatus may fall on a surface of a film to be patterned. In the case that the film is patterned by a dry etching process, due to shielding of the suspended particle, a portion of the film below the suspended particle cannot be etched away, and will leave a residue portion below the suspended particle.

For example, an active layer of a thin film transistor is formed by patterning; in this case, a photoresist layer formed on an a-Si film for forming the active layer is exposed and developed to obtain a patterned photoresist layer. As shown in FIG 1a, the suspended particle in the environment or the dry etching apparatus, which is capable of playing a role of masking, falls on a surface of the a-Si film , which is to be patterned to form the active layer. During the dry etching process, as shown in FIG 1b, the suspended particle will result in that the portion of the a-Si film located below it cannot be etched away; as shown in FIG 1c, after the patterned photoresist layer is stripped off, an etching residue (shown by a dashed box) is generated in the active layer of a-Si. According to a position of the etching residue in an array substrate of the display panel, as shown in FIG 1d, the etching residue may electrically connect the active layer of a-Si with a pixel electrode, or may electrically connect a data line with the pixel electrode, resulting in a bright spot, which seriously affect quality of the display panel.

Therefore, how to avoid the above-described etching residue generated in the dry etching process is a problem to-be-urgently solved.

### SUMMARY

According to embodiments of the disclosure, a film patterning method is provided. The method comprises: performing a dry etching process on a film to be patterned, so as to form a patterned film; removing a suspended particle on the patterned film; and performing another dry etching process on the patterned film after the suspended particle is removed, to form a final pattern of the film.

For example, before the performing the dry etching process on the film to be patterned to form the patterned film, the method further comprises: applying a photoresist on the film to be patterned; and exposing and developing the photoresist, to form a patterned photoresist layer on the film to be patterned.

For example, the performing the dry etching process on the film to be patterned to form the patterned film includes: performing the dry etching process on the film to be patterned by using the patterned photoresist layer covering the film to be patterned as a mask, so as to form the patterned film.

For example, the pattern of the patterned photoresist layer coincides with the final pattern of the film.

For example, the removing the suspended particle on the patterned film includes: performing a cleaning process on the patterned film.

For example, the cleaning process includes: liquid cleaning or gas cleaning.

For example, the performing the another dry etching process on the patterned film after the suspended particle is removed to form the final pattern of the film includes: performing the another dry etching process on the patterned film by using the patterned photoresist as a mask, to form the final pattern of the film.

For example, the patterned photoresist layer includes: a photoresist completely-reserved part covering the final pattern of the film and a photoresist partially-reserved part covering a region independent of the final pattern of the film.

For example, the removing the suspended particle on the patterned film includes: performing an ashing process on the patterned photoresist layer, to remove the photoresist partially-reserved part of the patterned photoresist layer and remove the suspended particle on the patterned film.

For example, the performing the another dry etching process on the patterned film after the suspended particle is removed to form the final pattern of the film includes: performing the another dry etching process on the patterned film by using the photoresist completely-reserved part which has underwent the ashing process as a mask, to form the final pattern of the film.

For example, the film to be patterned includes a film for forming an active layer, a film for forming an ohmic contact layer, a film for forming a source/drain electrode layer, a film for forming a pixel electrode layer, a film for forming a common electrode layer or a film for forming a touch electrode layer.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1a to FIG. 1d are respectively side structural schematic views after respective steps are executed in a process of forming an active layer by patterning;

FIG. 2 is a flow view of a film patterning method provided by embodiments of the present disclosure;

FIG. 3 is a partial flow view of the film patterning method provided by the embodiments of the present disclosure;

FIG. 4 is a flow view of the film patterning method provided by the embodiments of the present disclosure;

FIG. 5a to FIG. 5d are respectively side structural schematic views after respective steps are executed in the method provided in FIG. 4;

FIG. 6 is a flow view of the film patterning method provided by the embodiments of the present disclosure;

FIG. 7a to FIG. 7d are respectively side structural schematic views after respective steps are executed in the method provided in FIG. 6; and

FIG. 8a to FIG. 8d are respectively top structural schematic views after the respective steps are executed in the method provided in FIG. 6.

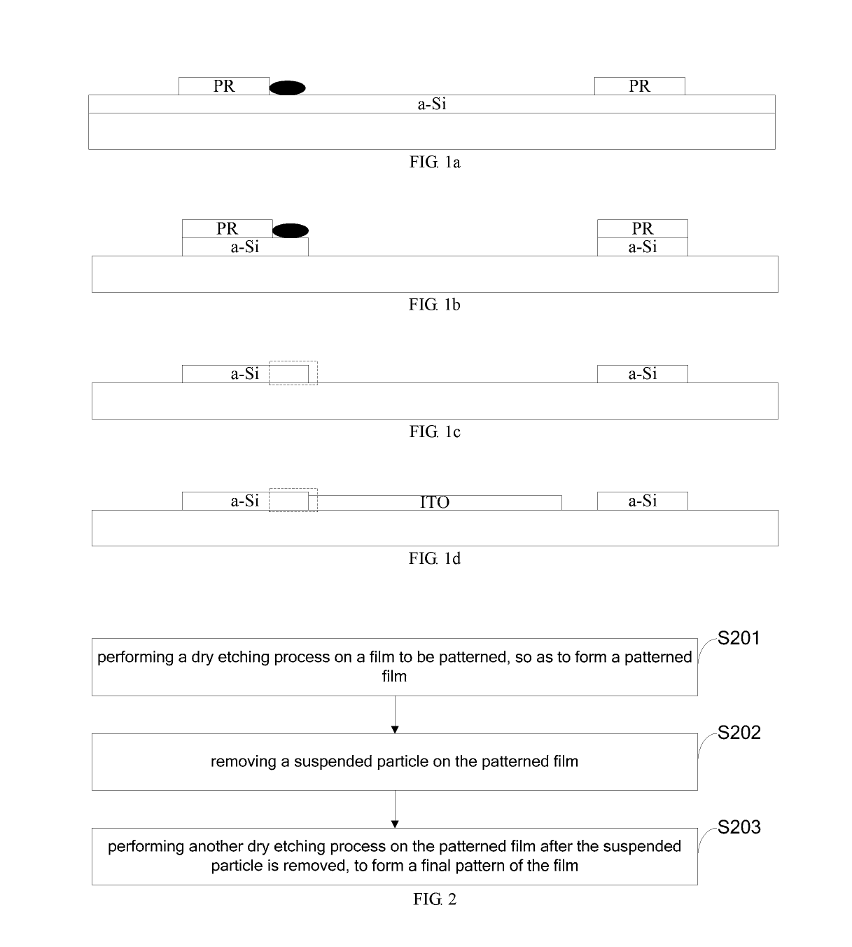

### DETAILED DESCRIPTION

In order to make objects, technical details and advantages of the embodiments of the invention apparent, the technical solutions of the embodiment will be described in a clearly and fully understandable way in connection with the drawings related to the embodiments of the invention. It is obvious that the described embodiments are just a part but not all of the embodiments of the invention. Based on the described embodiments herein, those skilled in the art can obtain other embodiment(s), without any inventive work, which should be within the scope of the invention.

Embodiments of the present disclosure provide a film patterning method. FIG. 2 is a flow view of a film patterning method provided by the embodiments of the present disclosure, and the method comprises:

S201: performing a dry etching process on a film to be patterned, so as to form a patterned film;

S202: removing a suspended particle on the patterned film;

S203: performing another dry etching process on the patterned film after the suspended particle is removed, to form a final pattern of the film.

In the above-described film patterning method provided by the embodiments of the present disclosure, in the case that the dry etching process is performed on the film to be patterned so as to form the patterned film, the suspended particle may exist and shield the film to be patterned, and then the portion of the film below the suspended particle, as shielded by the suspended particle, will not be etched away, and thus will generate an etching residue. By moving or completely removing the suspended particle on the patterned film and then performing another dry etching process on the patterned film after the suspended particle is removed or moved, the etching residue is etched away and does not exist any more, so that the a product yield is improved and a product quality is ensured.

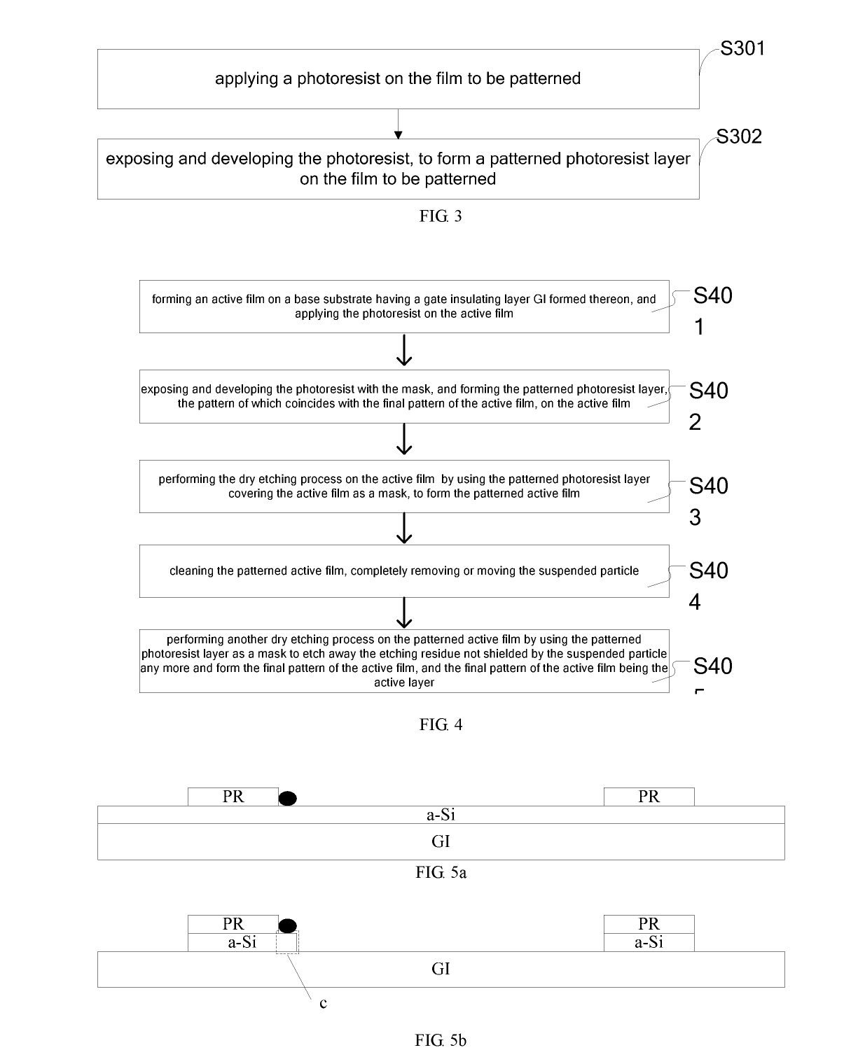

FIG. 3 is a partial flow view of the film patterning method provided by the embodiments of the present disclosure. For example, in the above-described film patterning method provided by the embodiments of the present disclosure, before step S201 of performing the dry etching process on the film to be patterned to form the patterned film, the method for example further comprises:

S301: applying a photoresist on the film to be patterned;

S302: exposing and developing the photoresist, to form a patterned photoresist layer on the film to be patterned.

For example, in the above-described method provided by the embodiments of the present disclosure, the exposing and developing the photoresist in the step S302 is implemented in a mode of shielding the photoresist with a mask and then exposing and developing the photoresist. According to different patterns of the mask, the pattern of the patterned photoresist layer for example include two types: one type is that the pattern of the patterned photoresist layer coincides with the final pattern of the film; and the other type is that the patterned photoresist layer includes two parts, of which one is a photoresist completely-reserved part covering the final pattern of the film, and the other is a photoresist partially-reserved part covering a region independent of the final pattern of the film.

For example, the photoresist is exposed and developed with the mask comprising a completely light-transmissive region and a completely light-shielding region, to form the pattern of the patterned photoresist layer which coincides with the final pattern of the film.

For example, the photoresist is exposed and developed with the mask comprising a completely light-transmissive region, a partially light-transmissive region and a completely light-shielding region, to form the pattern of the patterned photoresist layer having the photoresist completely-reserved part and the photoresist partially-reserved part at the same time. In one example, the mask is a half-tone mask, a gray-tone mask, or a mask having a slit, which is not limited here.

For example, exemplary, in the above-described method provided by the embodiments of the present disclosure, in step S201, in the case that the dry etching process is performed on the film to be patterned to form the patterned film, the dry etching process is performed on the film to be patterned to form the patterned film by using the patterned photoresist layer covering the film to be patterned as a mask.

For example, in the case that the pattern of the patterned photoresist layer coincides with the final pattern of the film, in step S201, after the dry etching process is performed on the film to be patterned, the patterned film should theoretically be the final pattern of the film; but as shielded by the suspended particle, the portion of the film below the suspended particle will not be etched away, and thus will generate the etching residue during the dry etching process, and therefore, the patterned film formed after the dry etching process not only includes the final pattern of the film, but also includes the etching residue.

For example, in the above-described method provided by the embodiments of the present disclosure, in step S202, in the case that the suspended particle covering the patterned film is removed, the suspended particle is moved or completely removed away by cleaning the patterned film to expose the etching residue below the suspended particle, and then the step S203 of performing another dry etching process on the patterned film to remove the etching residue and form the final pattern of the film is implemented.

For example, as described above, in the case that the patterned film is subjected to a cleaning process, the cleaning process includes: liquid cleaning or gas cleaning. For example, the suspended particle is flushed with clean water or blown with oxygen, nitrogen, etc., so that the suspended particle moves to change its position or the suspended particle is completely removed.

For example, the pattern of the patterned photoresist layer includes the photoresist completely-reserved part covering the final pattern of the film and the photoresist partially-reserved part covering the region independent of the final pattern of the film; in this case, after the step S201 of performing the dry etching process on the film to be patterned to form the patterned film, the patterned film should theoretically include two parts, one part being the final pattern of the film, and the other being a region independent of the final pattern of the film; but as shielded by the suspended particle, the portion of the film below the suspended particle will not be etched away, and thus will generate the etching residue during the dry etching process, and therefore, the patterned film formed after the dry etching process not only includes the two parts as described above but also include the etching residue.

For example, in the step S202 of removing the suspended particle covering the patterned film in the above-described method provided by the embodiments of the present disclosure, the patterned photoresist layer is subjected to an ashing process, so that the photoresist partially-reserved part of the patterned photoresist layer is removed, and the suspended particle is completely removed or moved to expose the etching residue below the suspended particle.

For example, in the step S203 of performing another dry etching process on the patterned film after the suspended particle is removed to form the final pattern of the film, the another dry etching process is performed on the patterned film to form the final pattern of the film by using the photoresist completely-reserved part which has underwent the ashing process as a mask.

For example, in the above-described film patterning method provided by the embodiments of the present disclosure, the film to be patterned includes a film for forming an active layer, a film for forming an ohmic contact layer, a film for forming a source/drain electrode layer, a film for forming a pixel electrode layer, a film for forming a common electrode layer or a film for forming a touch electrode layer. The above-described film for example is provided on a display substrate, and/or is provided on a touch substrate. It should be noted that, the embodiments of the present disclosure is not limited to the above-described film, and the above-described method provided by the embodiments of the present disclosure is applicable to any cases as long as the film needs to be patterned by the dry etching process.

The above-described film patterning method provided by the embodiments of the present disclosure will be further described with fabricating an active layer of a thin film transistor as an example.

Example One: the active layer is fabricated by using the mask comprising the completely light-transmissive region and the completely light-shielding region, FIG. 4 is a flow view of the film patterning method provided by the embodiments of the present disclosure, and the method comprises steps of:

S401: forming an active film formed of a-Si on a base substrate having a gate insulating layer GI formed thereon, and applying the photoresist PR on the active film;

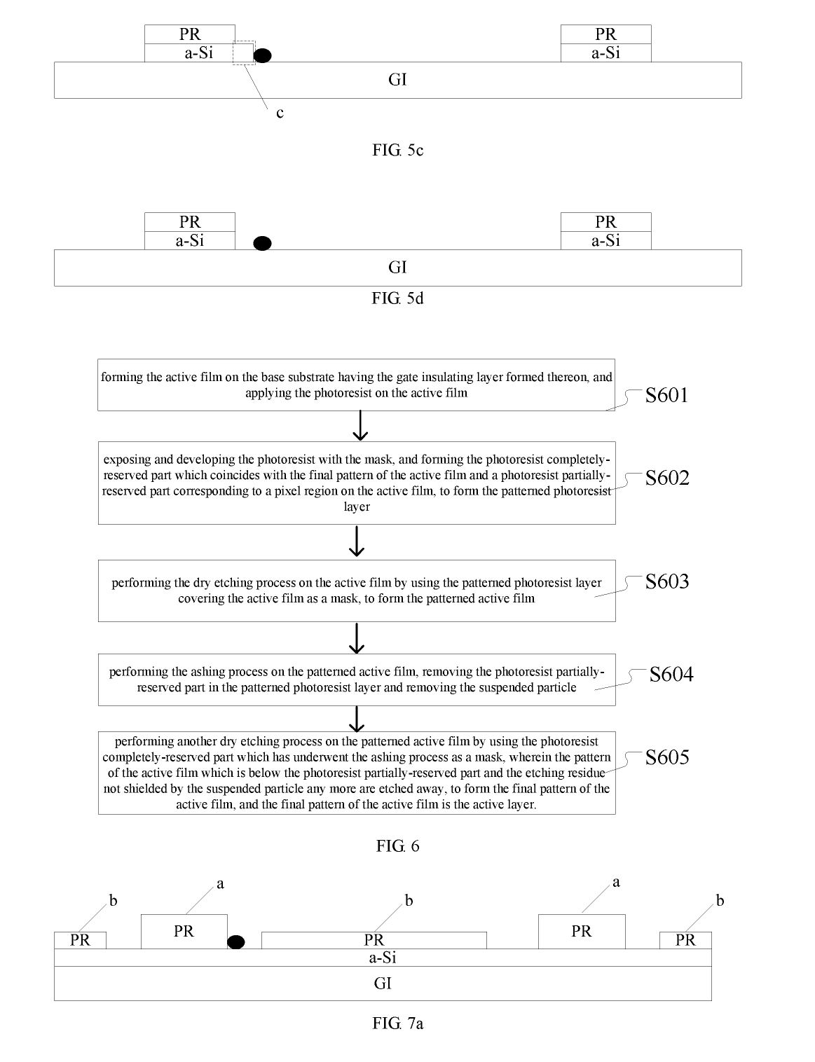

S402: exposing and developing the photoresist PR with the mask, and forming the patterned photoresist layer PR, the pattern of which coincides with the final pattern of the active film formed of a-Si, on the active film formed of a-Si; for example, FIG. 5a is a side structural schematic view after step S402 is executed, and the patterned photoresist layer PR is formed;

S403: performing the dry etching process on the active film of a-Si by using the patterned photoresist layer PR covering the active film of a-Si as a mask, to form the patterned active film of a-Si; FIG. 5b is a side structural schematic view after step S403 is executed, and the pattern of the patterned active film of a-Si includes the final pattern of the active film of a-Si covered by the patterned photoresist layer and an etching residue c which is shielded by the suspended particle and is not etched away;

S404: cleaning the patterned active film of a-Si, completely removing or moving the suspended particle; for example, FIG. 5c is a side structural schematic view after step S404 is executed; for example, air blowing is performed inside the dry etching apparatus for cleaning, and for example, the gas used is oxygen, nitrogen; for example, liquid washing outside the dry etching apparatus is performed; and for example, the liquid is clean water, which will not be limited here;

S405: performing another dry etching process on the patterned active film by using the patterned photoresist layer PR as a mask; for example, FIG. 5d is a side structural schematic view after step S405 is executed, the etching residue c not shielded by the suspended particle any more is etched away, to form the final pattern of the active film, and the final pattern of the active film is the active layer.

For example, the dry etching processes in step S403 and the another dry etching processes in step S405 use a same etching parameter, or use different etching parameters, which will not be limited here.

By the above-described steps S401 to S405, by completely remove the suspended particle on the etching residue or moving the suspended particle and then by etching away the etching residue by another etching process, the etching residue is completely eliminated.

Example Two: the active layer is fabricated with the mask comprising the completely light-transmissive region, the partially light-transmissive region and the completely light-shielding region, for example, FIG. 6 is a flow view of the film patterning method provided by the embodiments of the present disclosure, and the method comprises steps of:

S601: forming the active film of a-Si on the base substrate having the gate insulating layer GI formed thereon, and applying the photoresist PR on the active film;

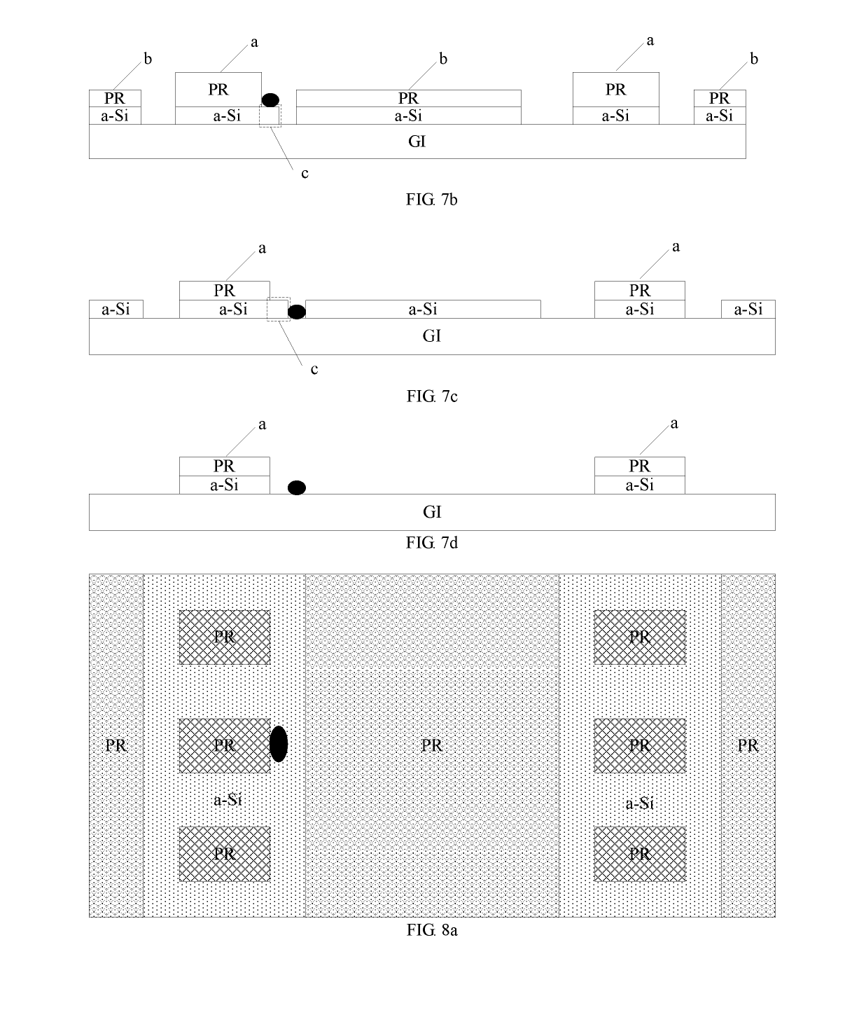

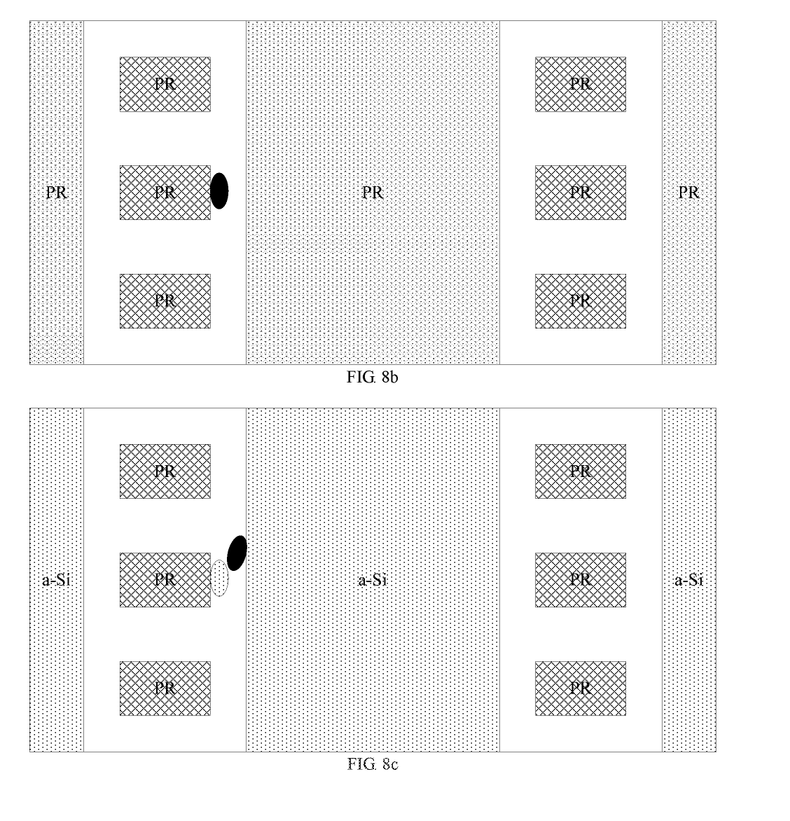

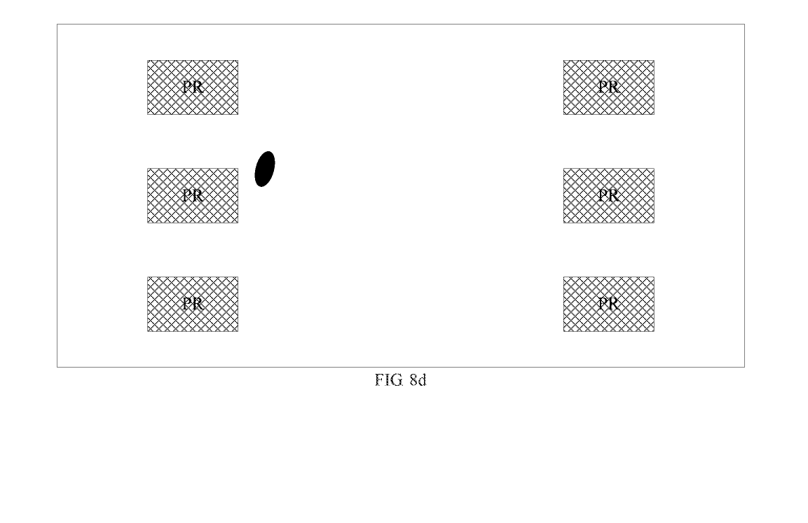

S602: exposing and developing the photoresist PR with the mask, and forming the photoresist completely-reserved part a which coincides with the final pattern of the active film of a-Si and a photoresist partially-reserved part b corresponding to a pixel region on the active film of a-Si, to form the patterned photoresist layer PR; for example, FIG. 7a is a side structural schematic view after step S602 is executed in the method provided by FIG. 6, and FIG. 8a is a top structural schematic view after step S602 is executed in the method provided by FIG. 6;

S603: performing the dry etching process on the active film of a-Si by using the patterned photoresist layer covering the active film of a-Si as a mask, to form the patterned active film of a-Si; for example, FIG. 7b and FIG. 8b are respectively a side structural schematic view and a top structural schematic view after step S603 is executed in the method provided by FIG. 6, the patterned active film of a-Si includes the final pattern of the active film which is below the photoresist completely-reserved part a, another pattern of the active film which is below the photoresist partially-reserved part b, and the etching residue c which is shielded by the suspended particle and which is not etched away and is located between the photoresist completely-reserved region and the photoresist partially-reserved region;

S604: performing the ashing process on the patterned active film of a-Si, removing the photoresist partially-reserved part in the patterned photoresist layer; FIG. 7c and FIG. 8c are respectively a side structural schematic view and a top structural schematic view after step S604 is executed in the method provided by FIG. 6; in the ashing process, the photoresist completely-reserved part in the patterned photoresist layer is thinned, and the suspended particle above the etching residue c is blown to move so that its position changes, and for example, oxygen is introduced during the ashing process;

S605: performing another dry etching process on the patterned active film of a-Si by using the photoresist completely-reserved part which has underwent the ashing process as a mask, FIG. 7d and FIG. 8d are respectively a side structural schematic view and a top structural schematic view after step S605 is executed in the method provided by FIG. 6, and the pattern of the active film of a-Si which is below the photoresist partially-reserved part and the etching residue c not shielded by the suspended particle any more are etched away, to form the final pattern of the active film of a-Si, and the final pattern of the active film of a-Si is the active layer.

For example, the dry etching process in step S603 and the another dry etching process in step S605 use a same etching parameter, or use different etching parameters, which will not be limited hereto.

In steps S601 to S605, during the ashing process performed on the patterned photoresist, by completely removing the suspended particle which causes the problem of the etching residue or by moving the suspended particle, and then by etching away the etching residue by another etching, the problem brought by the etching residue in the process of fabricating the active layer is completely eliminated.

Advantageous effect of the embodiments of the present disclosure includes: the embodiments of the present disclosure provide the film patterning method; in the case that the dry etching process is performed on the film to be patterned to form the patterned film, there may be the shielding of the suspended particle and the portion of the film below the suspended particle may not be etched away, and the etching residue may be generated; and thus, in the embodiments of the disclosure, by etching away the etching residue by moving or completely removing the suspended particle above the etching residue, and by performing the dry etching process again on the patterned film, existence of the etching residue is completely avoided in the final pattern of the film, so that the product yield is improved and the product quality is ensured.

It should be noted that one person skilled in the art can make various changes or modifications to the present disclosure without departure from the spirit and scope of the present disclosure. Thus, if such changes and modifications to the present disclosure are within the scope of the claims of the present disclosure and equivalent thereof, the present disclosure also intends to include all such changes and modifications within its scope.

The foregoing embodiments merely are exemplary embodiments of the present disclosure, and not intended to define the scope of the present disclosure, and the scope of the present disclosure is determined by the appended claims.

The present application claims priority of Chinese Patent Application No. 201510729734.8 filed on Oct. 30, 2015, the present disclosure of which is incorporated herein by reference in its entirety as part of the present application.

1. A film patterning method, comprising:
performing a dry etching process on a film to be patterned, so as to form a patterned film;
removing a suspended particle on the patterned film; and
performing another dry etching process on the patterned film after the suspended particle is removed, to form a final pattern of the film.

2. The method according to claim 1, wherein, before the performing the dry etching process on the film to be patterned to form the patterned film, the method further comprises:
applying a photoresist on the film to be patterned; and
exposing and developing the photoresist, to form a patterned photoresist layer on the film to be patterned.

3. The method according to claim 2, wherein, the performing the dry etching process on the film to be patterned to form the patterned film includes:
performing the dry etching process on the film to be patterned by using the patterned photoresist layer covering the film to be patterned as a mask, so as to form the patterned film.

4. The method according to claim 3, wherein, the pattern of the patterned photoresist layer coincides with the final pattern of the film.

5. The method according to claim 4, wherein, the removing the suspended particle on the patterned film includes: performing a cleaning process on the patterned film.

6. The method according to claim 5, wherein, the cleaning process includes: liquid cleaning or gas cleaning.

7. The method according to claim 3, wherein, the performing the another dry etching process on the patterned film after the suspended particle is removed to form the final pattern of the film includes: performing the another dry etching process on the patterned film by using the patterned photoresist as a mask, to form the final pattern of the film.

8. The method according to claim 3, wherein, the patterned photoresist layer includes: a photoresist completely-reserved part covering the final pattern of the film and a photoresist partially-reserved part covering a region independent of the final pattern of the film.

9. The method according to claim 8, wherein, the removing the suspended particle on the patterned film includes:
performing an ashing process on the patterned photoresist layer, to remove the photoresist partially-reserved part of the patterned photoresist layer and remove the suspended particle on the patterned film.

10. The method according to claim 9, wherein, the performing the another dry etching process on the patterned film after the suspended particle is removed to form the final pattern of the film includes:
performing the another dry etching process on the patterned film by using the photoresist completely-reserved part which has underwent the ashing process as a mask, to form the final pattern of the film.

11. The method according to claim 1,
wherein, the film to be patterned includes a film for forming an active layer, a film for forming an ohmic contact layer, a film for forming a source/drain electrode layer, a film for forming a pixel electrode layer, a film for forming a common electrode layer or a film for forming a touch electrode layer.

12. The method according to claim 2, wherein, the film to be patterned includes a film for forming an active layer, a film for forming an ohmic contact layer, a film for forming a source/drain electrode layer, a film for forming a pixel electrode layer, a film for forming a common electrode layer or a film for forming a touch electrode layer.

13. The method according to claim 3, wherein, the film to be patterned includes a film for forming an active layer, a film for forming an ohmic contact layer, a film for forming a source/drain electrode layer, a film for forming a pixel electrode layer, a film for forming a common electrode layer or a film for forming a touch electrode layer.

14. The method according to claim 4, wherein, the film to be patterned includes a film for forming an active layer, a film for forming an ohmic contact layer, a film for forming a source/drain electrode layer, a film for forming a pixel electrode layer, a film for forming a common electrode layer or a film for forming a touch electrode layer.

15. The method according to claim 5, wherein, the film to be patterned includes a film for forming an active layer, a film for forming an ohmic contact layer, a film for forming a source/drain electrode layer, a film for forming a pixel electrode layer, a film for forming a common electrode layer or a film for forming a touch electrode layer.

16. The method according to claim 6, wherein, the film to be patterned includes a film for forming an active layer, a film for forming an ohmic contact layer, a film for forming a source/drain electrode layer, a film for forming a pixel electrode layer, a film for forming a common electrode layer or a film for forming a touch electrode layer.

17. The method according to claim 7, wherein, the film to be patterned includes a film for forming an active layer, a film for forming an ohmic contact layer, a film for forming a source/drain electrode layer, a film for forming a pixel electrode layer, a film for forming a common electrode layer or a film for forming a touch electrode layer.

18. The method according to claim 8, wherein, the film to be patterned includes a film for forming an active layer, a film for forming an ohmic contact layer, a film for forming a source/drain electrode layer, a film for forming a pixel electrode layer, a film for forming a common electrode layer or a film for forming a touch electrode layer.

19. The method according to claim 9, wherein, the film to be patterned includes a film for forming an active layer, a film for forming an ohmic contact layer, a film for forming a source/drain electrode layer, a film for forming a pixel electrode layer, a film for forming a common electrode layer or a film for forming a touch electrode layer.

20. The method according to claim 10, wherein, the film to be patterned includes a film for forming an active layer, a film for forming an ohmic contact layer, a film for forming a source/drain electrode layer, a film for forming a pixel electrode layer, a film for forming a common electrode layer or a film for forming a touch electrode layer.
